(19) United States
(12) Patent Application Publication
(10) Pub. No.: US 2015/0059640 A1
(43) Pub. Date: Mar. 5, 2015

(54) METHOD FOR REDUCING GROWTH OF NON-UNIFORMITIES AND AUTODOPING DURING COLUMN III-V GROWTH INTO DIELECTRIC WINDOWS

(71) Applicant: Raytheon Company, Waltham, MA (US)

(72) Inventors: Jeffrey R. LaRoche, Lowell, MA (US); William E. Hoke, Wayland, MA (US); Thomas E. Kazior, Sudbury, MA (US)

(73) Assignee: Raytheon Company, Waltham, MA (US)

(21) Appl. No.: 14/010,954

(22) Filed: Aug. 27, 2013

(51) Int. Cl. C23C 16/18; C30B 29/40; C30B 1/02

(52) U.S. Cl. CPC C23C 16/18; C30B 1/023; C30B 29/40
USPC 117/8; 427/126.1; 427/487

(57) ABSTRACT

A method for depositing a column III-V material over a selected portion of a substrate through a window formed in a dielectric layer disposed over the selected portion of the substrate. The method includes forming a single crystal layer or polycrystalline layer over a field region of the dielectric layer adjacent to the window; and, growing, by MOCVD, column III-V material over the single crystal layer or polycrystalline layer and through the window over the selected portion of the substrate.

### TECHNICAL FIELD

This disclosure relates generally to methods for growing III-V materials and more particularly to forming by metalorganic chemical. vapor deposition (MOCVD) column III-V materials in a window formed in a dielectric layer.

### BACKGROUND AND SUMMARY

As is known in the art, many electronics applications incorporate both silicon and column III-V circuits due to their unique performance characteristics. The silicon circuits are typically CMOS circuits used for digital signals and the column circuits are for microwave, millimeter wave, and optical signals. One structure having both CMOS circuits and column III-V circuits is described in U.S. Pat. No. 8,212,294, with inventors Hoke et al., issued Jul. 3, 2013, and assigned to the same assignee as the present patent application and U.S. Pat. No. 7,994,550, with inventors Bettencourt et al, issued Aug. 9, 2011, and assigned to the same assignee as the present patent application.

As described therein, a silicon substrate has thereon: a dielectric layer (e.g. silicon dioxide layer) residing on a top silicon semiconductor layer having CMOS devices and a second silicon dioxide layer which is disposed between the top silicon semiconductor layer and the substrate. A window is etched through the layers to expose the upper surface portion of the silicon substrate and a column semiconductor material is grown epitaxially over the silicon substrate exposed by the window. Compound semiconductor devices such as high electron mobility transistors (HEMTs) and heterojunction bipolar transistors (HBTs) are themed on the column III-V material.

As is also known in the art, one technique used to form a column III-V epitaxial layer is molecular beam epitaxy (MBE) and another is by metaorganic chemical vapor deposition (MOCVD), a chemical vapor deposition method used to produce single or polycrystalline thin films. Generally, column III-V MOCVD crystal growth takes place at temperatures of a hundred to several hundred degrees higher than MBE growth and at much higher pressure. MOCVD growth is by chemical reaction of pyrolized molecules whereas MBE growth, typically of evaporated elements that then react to form the material. Advantages of MBE due to its lower growth temperature and pressure include the following:
lower residual strain from the Coefficient of Thermal Expansion (CTE) mismatch of epitaxial layers to non-native substrates (temperature),
more precise layer control (pressure and temperature),
line of site (nonselective) growth for heterogeneous integration of compound semiconductors with CMOS (pressure) allows arbitrary placement and size of compound semiconductor materials in windows,
reduced or eliminated autodoping from the silicon substrate, silicon device layer, and dielectric materials (temperature).

Advantages of MOCVD, on the other hand, particularly for nitride materials, include higher growth rate and wafer diameter scalability. Unfortunately, however, when forming a III-V layer though a window in a dielectric layer (deposited over the silicon layer where the CMOS devices are formed) using MOCVD, the deposition is not uniform. The cause of this non-uniformity is due to the higher growth pressures and temperatures of MOCVD growth as well as the lower reactivity of reagent molecules compared to elemental atoms (as in MBE growth) with the underlying surface. In MOCVD growth, this leads to selective area growth where the reactants deposited on the dielectric fail to nucleate and re-vaporize or have high surface mobility and travel to the window edges (increasing the reactant concentration at the window edges), while at the same time material is successfully deposited in the window. As a result, increased reactant concentration at the edges of windows leads to an enhanced growth rate of III-V material there. Additionally, the growth for smaller windows may be faster than larger windows, dense window areas may grow slower than sparse window areas, and all of the previously mentioned effects above may be at play at once.

The inventors have recognized that this growth non-uniformity is particularly detrimental to heterogeneous integration applications since the degree of III-V growth non-uniformity will likely be heavily dependent on the spacing, size and density of the growth windows. Thus, MOCVD selective epitaxy for heterogeneous integration of GaN and CMOS devices may limit the distribution, spacing and minimum size of device. Thus, these effects may severely limit the ability of MOCVD based growth to arbitrarily place III-V based devices for heterogeneous integration with CMOS.

This may be partially addressed in MOCVD by adjusting the growth temperature and pressure to the point where polycrystalline material is successfully deposited outside the window. However, this may compromise the quality of the device material grown within the windows. The initial nucleation of the device material on the substrate (or other III-V template layer) exposed at the bottom of the window is typically one of the most critical phases of material growth, and the optimum conditions may reside in a very narrow range of growth conditions. As a result, the inventors have decoupled the nucleation of device material (e.g., the column III-V deposited material) from the formation of polycrystalline material on a field region of the dielectric layer adjacent the window.

The inventors have solved this non-uniformity problem by forming a single crystal layer or polycrystalline layer (such as, for example, AlN, Si, Al₂₃, ZrO₂, SiC, TiN, or column III-V semiconductor layers such as, for example, GaN or metal such as W) on the surface portions over the amorphous dielectric layer field region (the portion of the dielectric layer outside the window) prior to forming by MOCVD the column III-V material. The formed material may be polycrystalline as deposited, or may be deposited amorphously and recrystallized through thermal treatment prior to the column III-V growth in windows. The layers may be formed by methods such as chemical vapor deposition (CVD), atomic layer deposition (ALD), electron beam evaporation, molecular beam epitaxy (MBE), metal organic vapor phase deposition (MOCVD), or by sputtering, for example.

A primary beneficial effect of the single crystal layer or polycrystalline layer is to act as a viable nucleation layer for MOCVD material outside the window area (where the column III-V material typically e-vaporizes or travels to the window edge). This in turn results in the uniform consumption of the MOCVD reactants and therefore the formation of column III-V material in windows having uniform growth rates within and between windows that are largely independent of window size, density and distribution over the wafer. Additionally, the formed layer can act as a diffusion barrier or be formed in combination with other layers to reduce auto-doping of the grown III-V layers. This barrier effect can be further enhanced by depositing the polycrystalline material after windows etching in a manner such that the exposed dielectric layers (such as SiO₂ and SiN) and semiconductor layers (such as Si) at the windows edges are covered by the deposited material. Thus, the formed layer's diffusion barrier property and its' ability to act as a site for crystal nucleation (over the field region) combine to suppress unintentional doping of the III-V layers and promote uniform consumption of III-V layer reactant species during MOCVD growth. As a result, doping of the grown III-V material is precisely controlledand any impact that growth. window size/placement/density would have on the uniformity of the grown III-V layer is reduced or eliminated dependent non-uniformity.

In accordance with the present disclosure, a method is provided for depositing a column III-V material over a selected portion of a substrate through a window formed in a dielectric layer disposed over the selected portion of the substrate, the method comprising: forming a single crystal layer or polycrystalline layer over a region of the dielectric layer adjacent to the window; and, growing, by MOCVD, a column III-V material over the single crystal layer or polycrystalline layer and through the window over the selected portion of the substrate.

In one embodiment, the polycrystalline layer is deposited polycrystalline material.

In one embodiment, the polycrystalline layer is deposited on the dielectric layer prior to formation of the window.

In one embodiment, the polycrystalline layer is deposited amorphously and thermally recrystallized prior to formation of the window.

In one embodiment, the polycrystalline layer is deposited amorphously and then thermally re-crystallized to provide a single crystal layer at the bottom of the window to provide a column III-V growth template. The polycrystalline layer in this embodiment is not removed at the bottom of the window prior to column III-V material growth, but is instead grown on as a column III-V growth template since the deposited amorphously and then thermally re-crystallized layer is now a single crystal layer at the bottom of the window. An example of this would be AlN deposited by sputtering or ALD (atomic layer deposition).

In one embodiment, the polycrystalline layer is deposited as a mixture of crystalline (in windows) and polycrystalline (over amorphous dielectric field region outside window) after window formation but prior to column III-V growth. The polycrystalline layer in this embodiment is not removed at the bottom of the window prior to column III-V material growth, but is instead grown on as a column III-V growth template since the deposited amorphously and then thermally re-crystallized amorphously deposited polycrystalline layer is not a single crystal layer at the bottom of the window. An example of this would be AlN deposited by MBE.

In one embodiment, the polycrystalline layer is deposited polycrystalline material on the field dielectric and window edges near completion of windows formation when only a thin residual layer of dielectric remains at the bottom of the window over the column III-V growth template layer or substrate. The polycrystalline layer and residual dielectric layer in the window are then removed to allow growth of the column III-V layer in the window.

In one embodiment, the polycrystalline layer is deposited as an amorphous material on the field dielectric and window edges near completion of window when only a thin residual layer of oxide remains at the bottom of the window over the III-V growth template layer or substrate, The polycrystalline layer is then thermally recrystallized. The polycrystalline layer and residual dielectric layer are then removed in the window to allow growth of the III-V layer in the window.

In one embodiment, the polycrystalline layer is deposited as an amorphous material on the field dielectric and windows edges near completion of window formation when only a thin residual layer of dielectric remains at the bottom of the window over the III-V growth template layer or substrate. The amorphous layer and residual dielectric layer are then removed to allow growth of the III-V layer in the window. The polycrystalline layer is then thermally recrystallized prior to III-V growth.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIGS. 1A-1D are cross sectional sketches at various steps in a method for depositing a column III-V material over a selected portion of a substrate through a window formed in a dielectric layer disposed over the selected portion of the substrate according to the disclosure;

FIGS. 2A-2E are cross sectional Sketches at various steps in a method for depositing a column III-V material over a selected portion of a substrate through a window formed in a dielectric layer disposed over the selected portion of the substrate according to another embodiment of the disclosure;

FIGS. 3A-3F are cross sectional sketches at various steps in a method for depositing a column III-V material over a selected portion of a substrate through a window formed in a dielectric layer disposed over the selected portion of the substrate according to another embodiment of the disclosure;

FIGS. 4A and 4B are cross sectional sketches at various steps in a method for depositing a column III-V material over a selected portion of a substrate through a window formed in a dielectric layer disposed over the selected portion of the substrate according to another embodiment of the disclosure;

FIGS. 5A -5C are cross sectional sketches at various steps in a method for depositing a column III-V material over a selected portion of a substrate through a window formed in a dielectric layer disposed over the selected portion of the substrate according to another embodiment of the disclosure;

FIGS. 6A-6D are cross sectional sketches at various steps in a method for depositing a column III-V material over a selected portion of a substrate through a window formed in a dielectric layer disposed over the selected portion of the substrate according to another embodiment of the disclosure; and

FIGS. 7A-7D are cross sectional sketches at various steps in a method for depositing a column III-V material over a selected portion of a substrate through a window formed in a dielectric layer disposed over the selected portion of the substrate according to another embodiment of the disclosure;

Like reference symbols in the various drawings indicate like elements.

### DETAILED DESCRIPTION

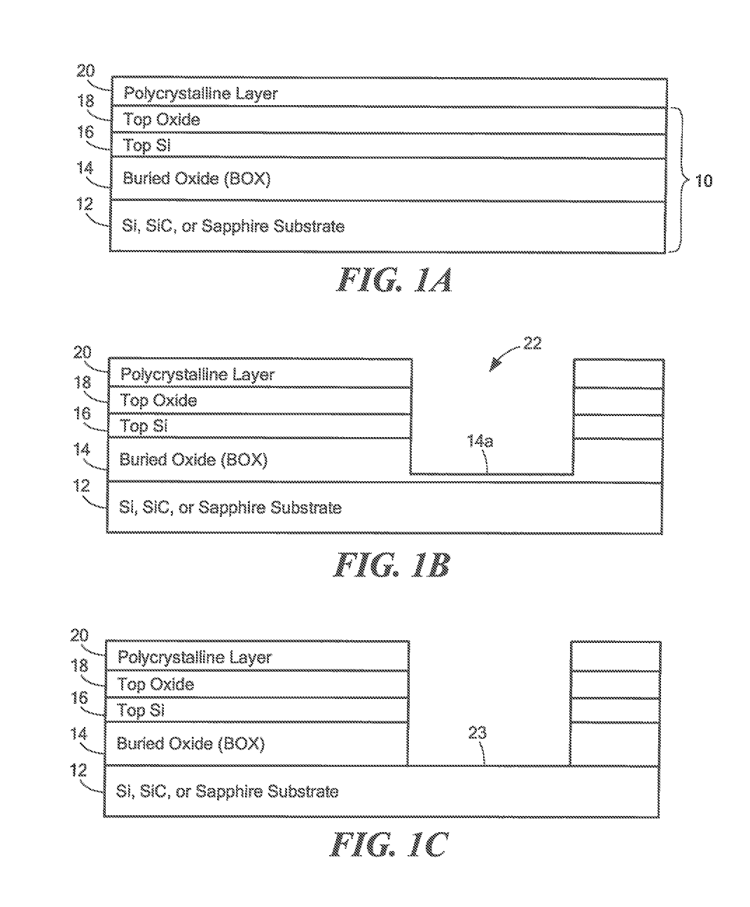

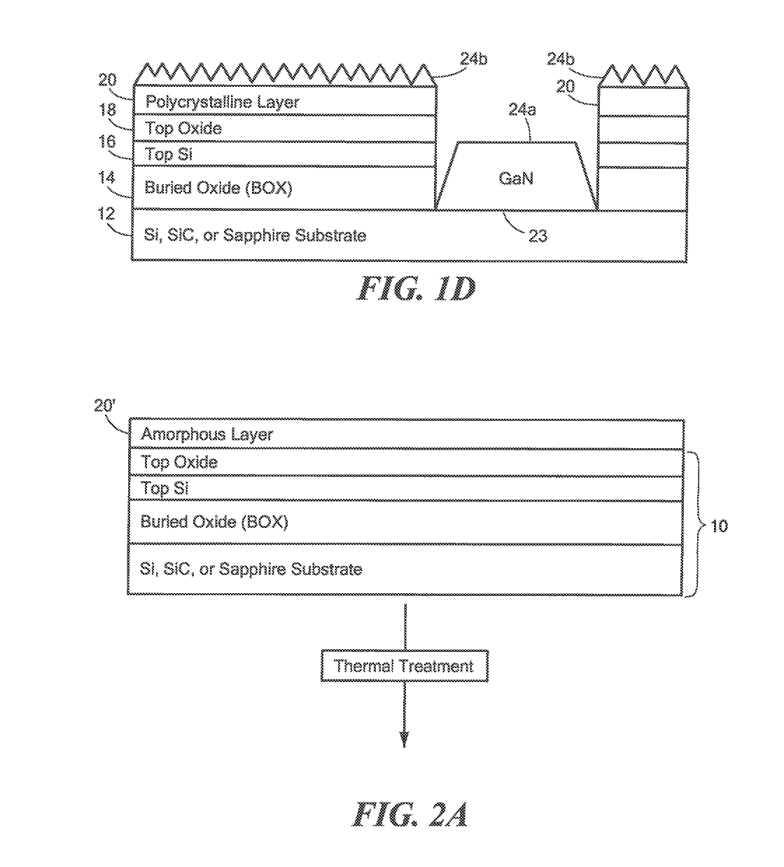

Referring now to FIG. 1A, a structure 10 is shown having: a substrate 12, here for example, Si, SiC or Sapphire; a buried oxide, dielectric layer (BOX) 14, here, for example silicon dioxide, on the substrate 12; a silicon layer 16 on the BOX layer 14, a second dielectric layer 18, here silicon dioxide, on the silicon layer 16. The second dielectric layer 18 may be considered as a field dielectric layer. Further, CMOS or other silicon devices may be formed in the silicon layer, 16.

Next, referring to FIG. 1B, a polycrystalline layer 20 is formed over the surface of the silicon oxide layer 18 as shown by atomic layer deposition (ALD), plasma enhanced ALD, molecular beam epitaxy (MBE), plasma enhanced MBE, metal organic chemical vapor deposition (MOCVD), physical vapor deposition (PVD/sputtering), chemical vapor deposition (CVD), reactive sputtering, evaporation, or reactive evaporation. Here, the polycrystalline layer 20 can be, for example, AlN, Si, Al₂O₃, SiC, TiN, or column III-V semiconductor layers such as, for example, GaN or metal such as W. Next, a window 22 is dry etched through the layers 20, 18, 16 and partially into layer 14 leaving a thin layer 14a of the BOX layer 14, as shown in FIG. 1B.

Next, referring to FIG. 1C, the thin layer 14a (FIG. 1B) of BOX layer 14 is removed with a wet etch to expose a selected portion 23 of the surface of the substrate 12, as shown.

Next, referring to FIG. 1D, a layer of column III-V material, here, for example, GaN, is grown over the surface of the structure shown in FIG. 1C, here by MOCVD. It is noted that the MOCVD growth forms polycrystalline GaN layer 24b on the polycrystalline layer 20, but forms as a single crystal, epitaxial, layer 24a GaN on the selected surface portion 23 of the substrate 12, as shown.

Thus, in connection with the embodiment described above in connection with FIGS. 1A-1D, the polycrystalline layer 24 is deposited on the field dielectric layer 18 prior to formation of the window 22.

As noted above, by depositing the polycrystalline layer 20 on the surface portions over the dielectric field region of the dielectric layer 18, prior to forming by MOCVD the column material 24a, 24b, the polycrystalline layer 20 acts as viable nucleation layer for MOCVD material outside the window area (where the column III-V material typically re-vaporizes). This in turn results in the uniform consumption of the MOCVD reactants and therefore the formation column III-V material 24a in the window 22 having uniform growth rates that are largely independent of window size, density and distribution over the wafer. Additionally, the deposited polycrystalline layer 20 can act as diffusion barriers or deposited. in combination with other layers to reduce auto-doping of the grown III-V layers. The use of the deposited polycrystalline layer 20 also providing a diffusion barrier layer that limits unintentional dopant diffusion, and promotes polycrystalline growth in the field or region of interest to further suppress dopant diffusion during the MOCVD process and uses the polycrystalline growth in the field to promote uniform consumption of reactant species during MOCVD growth thereby reducing/eliminating any growth window size/placement/density dependent non-uniformity. The layers 24b and 20 are later removed during device processing or have vias formed in them to allow heterogeneous integration with device present on Si layer 16.

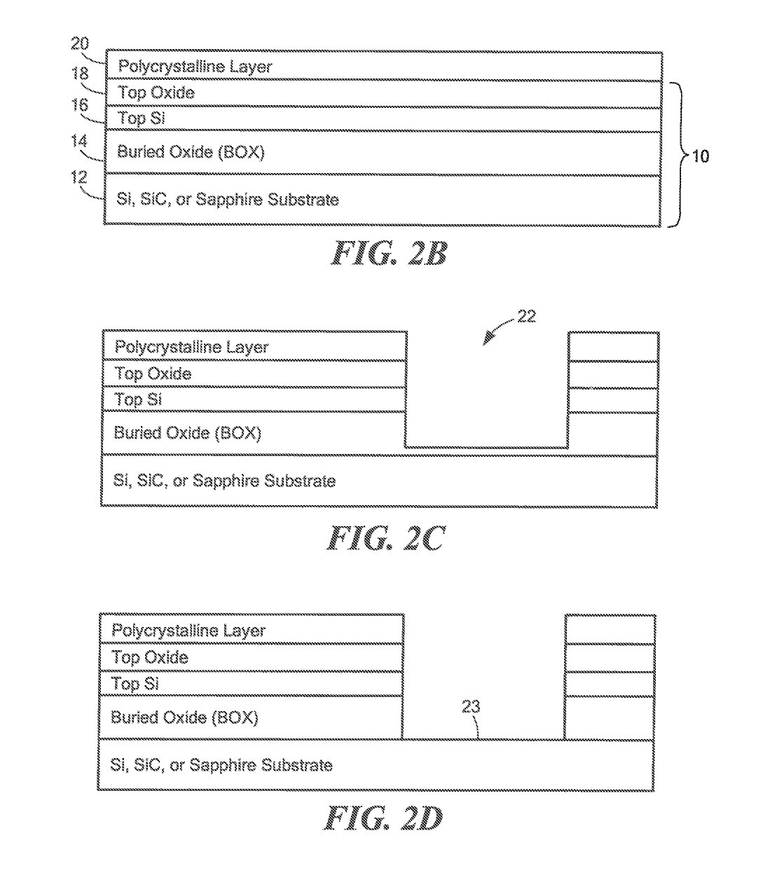

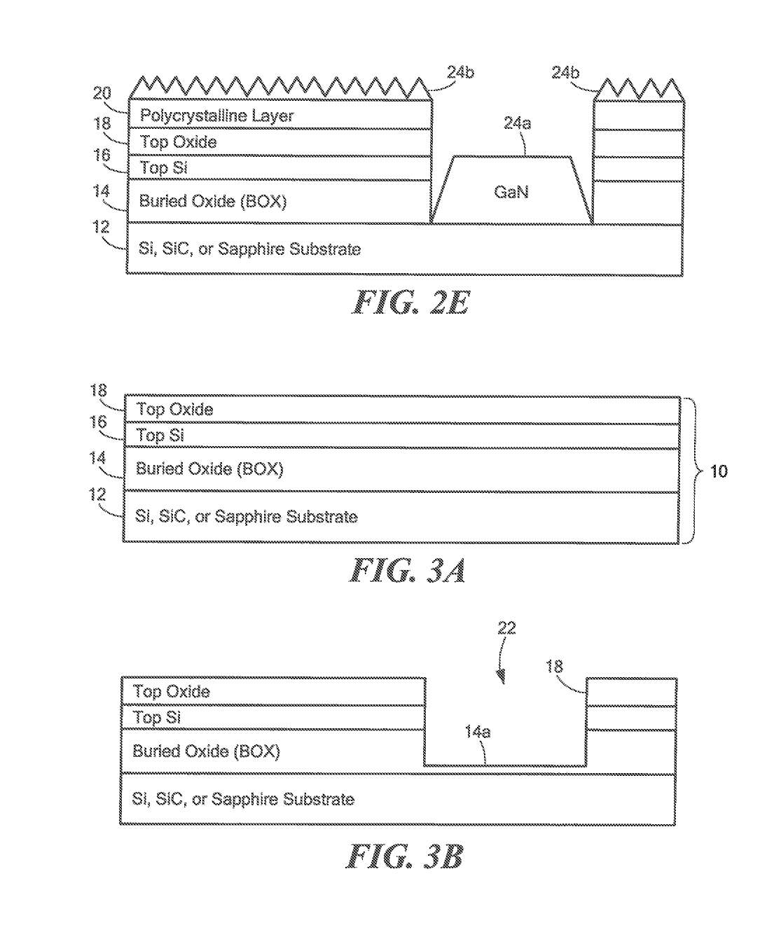

Referring now to FIGS. 2A-2C, here, in this embodiment, the polycrystalline layer 20 is first deposited amorphously, by methods such as ALD and plasma enhanced chemical vapor deposition (PECVD), as a layer 20′ in FIG. 2A. Layer 20′ is subsequently thermally re-crystallized into the polycrystalline layer 20, as shown in FIG. 2B prior to formation of the window 22 as shown in FIG. 2C. The processing then continues as shown and as described above in connection with FIGS. 1C and 1D.

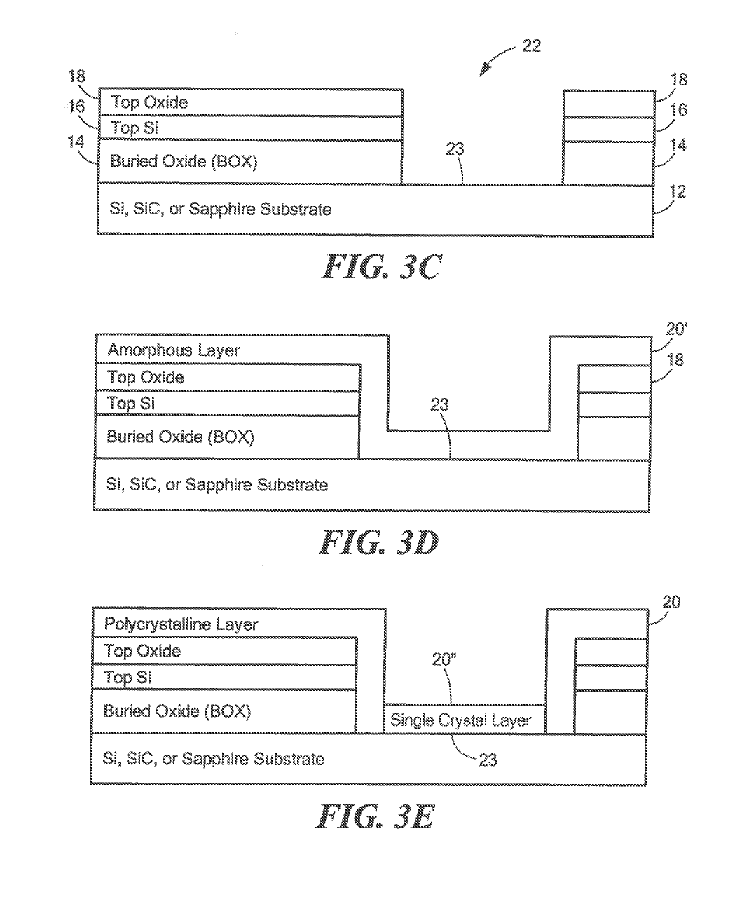

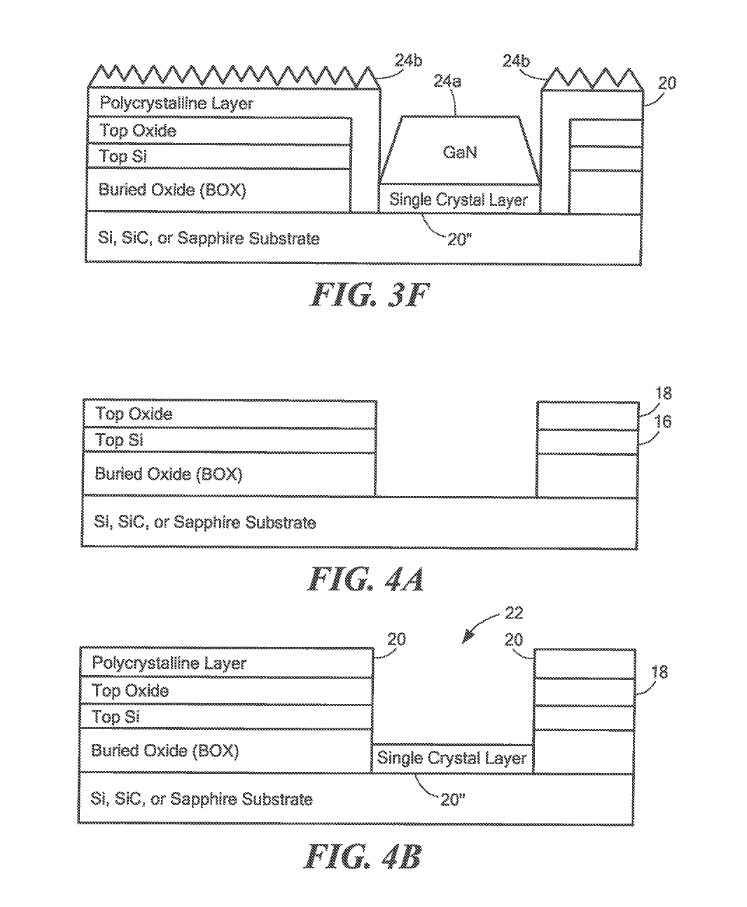

Referring now to FIGS. 3A-3F the structure 10, shown in FIG. 3A, is first subjected to a dry etch through the layers 18, 16 and partially into layer 14 leaving a thin layer 14a of the BOX layer 14, as shown in FIG. 3B. Next, referring to FIG. 3C, the thin layer 14a (FIG. 1B) of BOX layer 14 is removed with a wet etch to expose a selected portion 23 of the surface of the substrate 12, as shown.

Next, the polycrystalline layer 20 is first deposited amorphously, by methods such as ALD and plasma enhanced chemical vapor deposition (PECVD), as a layer 20′ in FIG. 3D over the surface of the structure shown in FIG. 3C including over side portions of the window 22 and onto the exposed surface portions 23 of the substrate 22, as shown in FIG. 3D, and is subsequently thermally re-crystallized into the polycrystalline layer 20, as shown in FIG. 2C; it being noted that the portion of the amorphously deposited layer 20′ deposited on the exposed surface portion 23 of the substrate 10 forms as a single crystal layer 20″ (as a result of the thermal re-crystallization process), as shown in FIG. 3E. This single crystal layer 20″ serves as a growth template for the column III-V material. More particularly, the structure shown in FIG. 3E has a layer of column III-V material, here, for example, GaN, grown over the surface of the structure shown in FIG. 3E, here by MOCVD. It is noted that the MOCVD growth forms polycrystalline GaN layer 24h on the polycrystalline layer 20, but forms as a single crystal, epitaxial, layer 24a GaN on the single crystalline layer 20″ column III-V growth template, as shown in FIG. 3F.

Thus, in the embodiment described above in connection with FIGS. 3A-3F, the thermally recrystallized layer 20″ is not removed at the bottom of the window prior to column III-V material growth, but is instead grown on as a column III-V growth template since the amorphously deposited layer 20′ thermally re-crystallized layer is now a single crystal layer 20″ at the bottom of the window. An example of this would be AlN deposited by sputtering, atomic layer deposition (ALD), or reactive evaporation.

Referring now to FIGS. 4A 4B, the structure 10 is processed as described above in connection with 3A and 3B; here however, after removal of the thin layer 14a (FIG. 3B) of BOX layer 14, the polycrystalline layer 20 is deposited as mixture of single crystal layer 20″ (in window 22) and as the polycrystalline layer 20 (over amorphous dielectric field region outside window 22) after window formation but prior to column III-V growth. The single crystal layer 20″ in this embodiment is not removed at the bottom of the window 22 prior to column III-V material growth, but is instead grown on as a column III-V growth template at the bottom of the window 22, as shown in FIG. 4B. An example of this would be AlN deposited by MBE. Another example may be reactive evaporation of AlN. In that case, however, the AlN would likely not deposit as single crystal and would therefore need to be thermally recrystallized from a 20′ to a 20″ layer at the bottom of window 22.

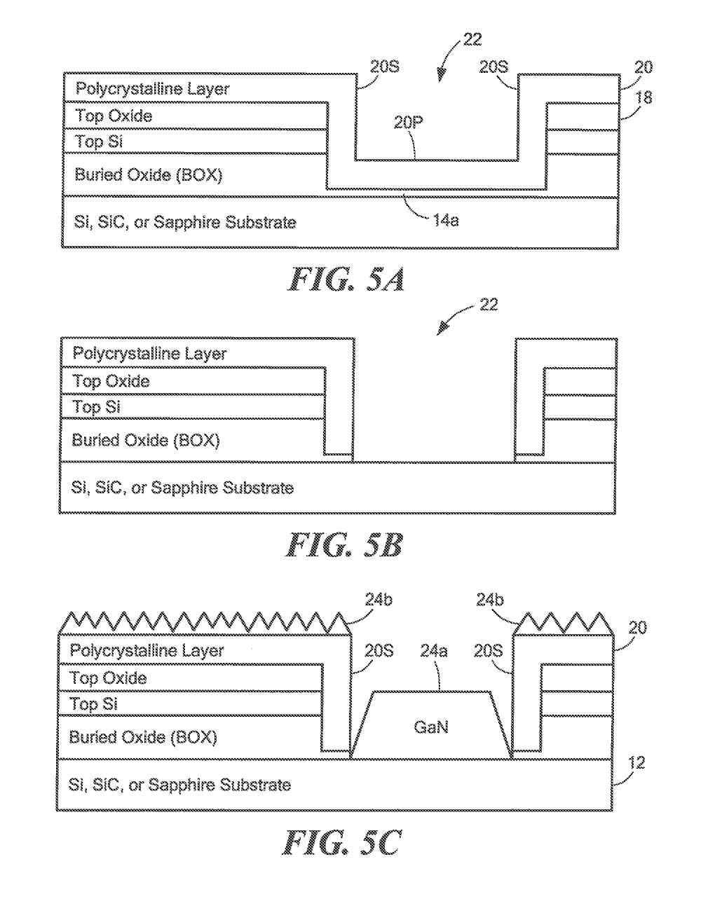

Referring now to FIGS. 5A 5C, the structure shown in FIG. 3B still having the thin layer 14a of BOX layer 14, has the polycrystalline layer 20 deposited polycrystalline on the field dielectric layer 18 and also a portion 208 and 20P on the sides or edges of the window 22 near completion of window formation when only a thin residual layer of dielectric layer 14a remains at the bottom of the window 22, as shown in FIG. 5A. The portion of the polycrystalline layer 20P on the bottom of the window 22 and residual dielectric layer 14a are then removed, as shown in FIG. 5B to allow growth of the column III-V layer 24a in the window 22, as shown in FIG. 5C.

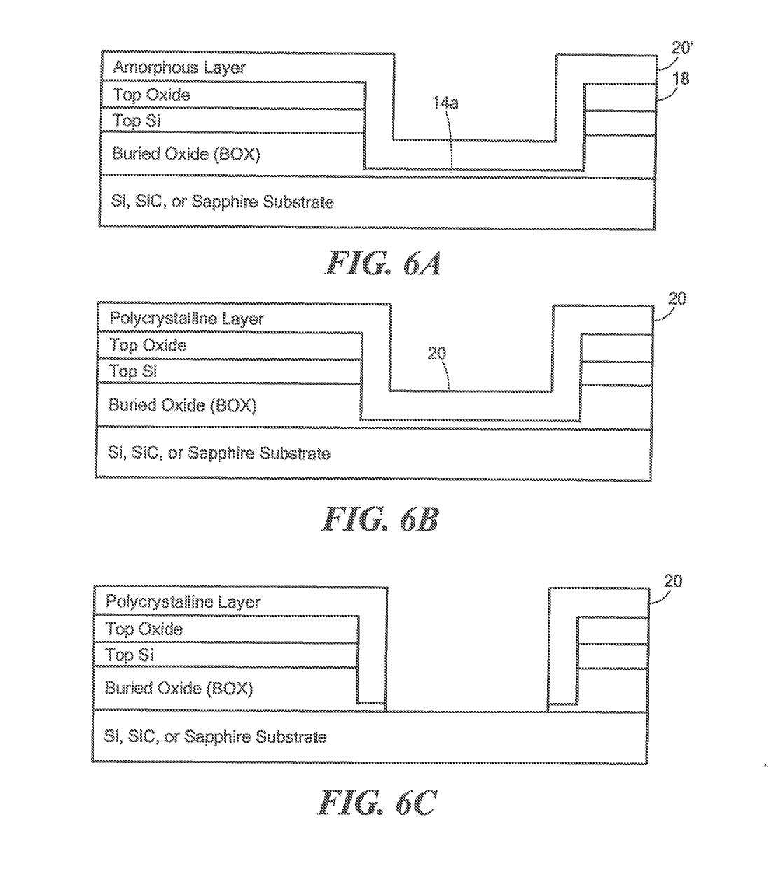

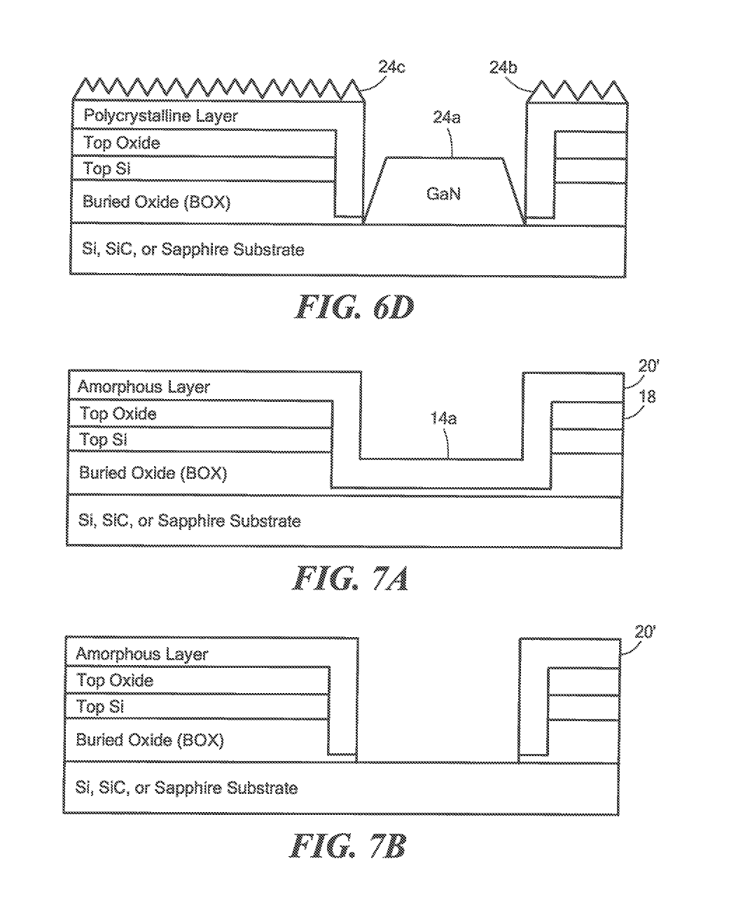

Referring now to FIG. 6A-6D, the structure shown in FIG. 3B, still having the thin layer 14a of BOX layer 14, has the polycrystalline layer 20 (FIG. 6B) first deposited as an amorphous material, by methods such as ALD and plasma enhanced chemical vapor deposition (PECVD), to form amorphous layer 20′ on the field dielectric 18, in the window, and along the window sidewalls near completion of window when only a thin residual layer 14a of silicon oxide remains at the bottom of the window, as shown in FIG. 6A. The amorphous layer 20′ is then thermally recrystallized to polycrystalline layer 20, as shown in FIG. 6B. The polycrystalline layer 20 and residual dielectric layer 14a are then removed in the bottom of window area 22 to allow growth of the III-V layer 24a in the window, as shown in FIGS. 6C and 6D.

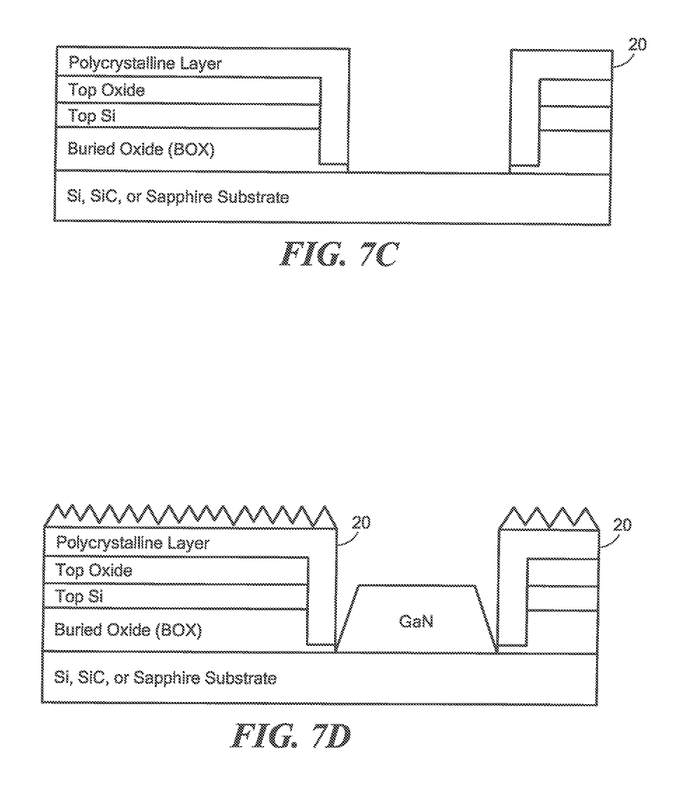

Referring now to FIGS. 7A-7D, the structure shown in FIG. 3B still having the thin layer 14a of BOX layer 14 the polycrystalline layer 20 (FIG. 7C) is deposited as an amorphous material, by methods such as ALD and plasma enhanced chemical vapor deposition (PECVD), to form amorphous layer 20′ on the field dielectric layer 18 and window edges near completion of window formation when only a thin residual layer 14a of dielectric remains at the bottom of the window. The amorphous layer 20′ and residual oxide layer 14a are then removed in the bottom of window area 22, as shown in FIG. 7B. The amorphous layer 20′ is then thermally recrystallized into polycrystalline layer 20 in FIG. 7C. The III-V layer is grown in the window, as shown in FIG, 7D.

After forming the III-V layer as described above in connection with FIGS. 1A through 7D, the polycrystalline layer 20 is removed by dry or wet etching selectively to the underlying oxide layer 18. For instance, the III-V material gallium nitride (GaN) is usually dry etched using BC13/C12 mixtures in reactive ion etching (RIE) or inductively couple plasma (ICP) etching chambers. During wet and dry etching processes the single crystal layer 24a (grown over the selected portion of the substrate in the window) is protect by masking. The masking materials may be metal, resist or dielectric based (such as SiNx, SiO2, or dielectric stacks) or combinations of thereof. After removal of layer 20, CMOS devices, not shown, are formed in the silicon layer 16 by any conventional technique.

A number of embodiments of the disclosure have been described. Nevertheless, it will be understood that various modifications may be made without departing from the spirit and scope of the disclosure. For example a single crystal layer may be used in place of the polycrystalline layer 20. For example the single crystal layer may be from a Si donor wafer or other compound semiconductors (such as GaN) that would have been grown epitaxially (by MOCVD or MBE) as a single crystal on a donor wafer and bonded and transferred to the dielectric layer 18 in a fabrication approach similar silicon on insulator (SOI) wafer fabrication. The bonding process could be oxide/oxide wafer bonding or other technique such as anodic bonding. Accordingly, other embodiments are within the scope of the following claims.

What is claimed is:

1. A method for depositing a column III-V material over a selected portion of a substrate through a window formed in a dielectric layer disposed over the selected portion of the substrate, the method comprising:
forming a single crystal layer or polycrystalline layer over a region of the dielectric layer adjacent to the window; and, growing, by MOCVD, a single crystal column III-V material over the single crystal layer onto selected portion of the substrate in the window.

2. The method recited in claim I wherein the polycrystalline layer is deposited as polycrystalline material.

3. The method recited in claim 1 wherein the polycrystalline layer is deposited on the dielectric layer prior to formation of the window.

4. The method recited in claim I wherein the polycrystalline layer is deposited amorphously and thermally re-crystallized prior to formation of the window.

5. The method recited in claim I wherein the polycrystalline layer is deposited amorphously after window formation and thermally re-crystallized to provide a single crystal layer on the exposed portion. of the substrate subsequent to formation of the window.

6. The method recited in claim 1 wherein the polycrystalline layer is deposited amorphously after window formation and then thermally re-crystallized to provide a single crystal layer at the bottom of the window to provide growth template for the single crystal column III-V material.

7. The method recited in claim 1 wherein the polycrystalline layer is deposited as mixture of single crystal material in the window and polycrystalline material over the dielectric layer outside window after formation of the window.

8. The method recited in claim 7 wherein the polycrystalline layer is deposited as mixture of single crystal material in the window and polycrystalline material over the dielectric layer outside window after the window formation and prior to column III-V growth,

9. The method recited in claim 1 wherein the polycrystalline layer is deposited on the dielectric layer and sides of the window edges.

10. The method recited in claim 1 wherein the polycrystalline layer is deposited as an amorphous material on the dielectric layer and sides of the window and on the bottom of the window over the exposed selected portion of the substrate, and then thermally re-crystallized to provide a single crystal growth template for the column III-V layer at the bottom of the window, with remaining portions of the amorphous deposited polycrystalline layer outside of the bottom of the window being re-crystallized to provide a polycrystalline portion.

11. The method recited in claim 1 wherein:
the polycrystalline layer is deposited as an amorphous material on the dielectric layer, sides of the window, and a portion of remaining dielectric disposed over the selected portion of the substrate at the bottom of the window;
removing the amorphous material and portions of the dielectric from the selected portion of the substrate at the bottom of the window;
thermally recrystallizing remaining portions of the amorphously deposited polycrystalline layer; and
growing column III-V material as a single crystal material on the exposed selected portion. of the substrate at the bottom of the window,

12. The method recited in claim 1 wherein:
the polycrystalline layer is deposited as an amorphous material on the dielectric layer, sides of the window, and a portion of remaining dielectric disposed over the selected portion of the substrate at the bottom of the window;
thermally recrystallizing the amorphously deposited polycrystalline layer; and
removing the polycrystalline material and portions of the dielectric from the selected portion of the substrate at the bottom of the window;
growing column III-V material as a single crystal material on the exposed selected portion of the substrate at the bottom of the window.

13. The method recited in claim 1 wherein:
the polycrystalline layer is deposited on the dielectric layer, sides of the window, and a portion of remaining dielectric disposed over the selected portion of the substrate at the bottom of the window; and
removing the polycrystalline material and portions of the dielectric from the selected portion of the substrate at the bottom of the window;
growing column III-V material as a single crystal material on the exposed selected portion of the substrate at the bottom of the window.

14. A method for depositing a column III-V material over a selected portion of a substrate through a window formed in a dielectric layer disposed over the selected portion of the substrate, the method comprising:
growing, by MOCVD, column III-V material as a single crystal onto selected portion of the substrate in the window while growing the column III-V material as polycrystalline material over a region of the dielectric, layer adjacent to the window.
